(19) United States
(12) Patent Application Publication
(10) Pub. No.: US 2008/0211083 A1
(43) Pub. Date: Sep. 4, 2008

(54) Electronic package and manufacturing method thereof

(75) Inventors: Joon-Seok Kang, Suwon-si (KR); Sung Yi, Suwon-si (KR); Jae-Cheon Doh, Cheonan-si (KR); Suk-Youn Hong, Suwon-si (KR); Sun-Kyong Kim, Seoul (KR); Jong-Hwan Baek, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/007,590

(22) Filed: Jan. 11, 2008

(30) Foreign Application Priority Data
Mar. 2, 2007 (KR) 10-2007-0020937

(51) Int. Cl. H01L 23/485; H01L 21/60

(52) U.S. Cl. 257/700; 438/107; 257/E23.019; 257/E21.507

(57) ABSTRACT

An electronic package and a manufacturing method thereof are disclosed. The electronic package manufacturing method, which includes providing a printed circuit board (PCB) having one surface on which a first chip is mounted; attaching one surface of a second chip on the other surface of the PCB, a pad being formed in the other surface of the second chip; encapsulating the second chip by coating the other surface of the PCB with an insulation material; and processing a first via by punching a hole on the insulation material, the first via being electrically interconnected to the pad, can perform stable handling in a process of mounting a semiconductor chip, make it unnecessary to add a process for chip encapsulation and realize a system in package having high density and high reliability.

### CROSS-REFERENCE TO RELATED APPLICATIONS

This application claims the benefit of Korean Patent Application No. 10-2007-0020937, filed on Mar. 2, 2007, in the Korean Intellectual Property Office, the disclosure of which is incorporated herein in its entirety by reference.

### BACKGROUND

1. Technical Field

The present invention relates to an electronic package and a manufacturing method thereof.

2. Description of the Related Art

An electronic package is performed by the technology, efficiently packaging a device used in an electronic products, which includes a chip packaging technology modularizing semiconductor chips, cut to pieces, by adhering and electrically interconnecting the semiconductor chips to a substrate. Through the compact and outstandingly electrically performed surface-mounted package technology from the initial insert type packaging technology, the electronic package has been very speedily enveloped toward the today's trend of small-sized and light-weighted surface-mounted types such as a ball grid array (BGA) and a chip scale package (CSP).

The current CSP to which a flip chip method is applied necessarily uses a bump ball technology for the electrical interconnection between chips or between chips and the substrate. The bump ball technology may generate the solder fatigue failure due to thermal stress in a connection part with a chip pad, which has an affect on the reliability. Also, the number of input/output of the package may be restricted due to the limitation of the minute size of the bump ball.

The number of input/output of chips, which has risen sharply in a current electronic part industry, results in the multifunctional and multiplex trend of the electronic package manufactured by using chips. Referring to the foregoing examples, the method, which can solve the problem that the product's reliability is lowered by the solder fatigue failure without the limitation of the number of input/output by packaging an electrode pad of the chip as the chip scale without using the solder bump, has been developed. Here, the solder fatigue failure may be generated due to using the solder bump.

For example, the ‘build-up’ technology, which builds up a metal layer from a pad pattern of an upper part of the chip, was developed as illustrated in FIG. 1. However, in the case of the build-up technology, the overall size of a package is increased in the process forming a package structure such as a system in package (SIP). In other words, since each chip is required to be mounted in a horizontal array type in the case of the package using a multi-chip, it is difficult to minimize the pattern size of all sets.

The conventional flip chip BGA package using no solder bump can package the chip having a high density input/output pad and have no problem caused by the solder fatigue because of using no bump ball. However, the conventional flip chip BGA package has the following problems. An additional process for molding the chip mounted in the package is necessarily needed. Since an adhesive layer is required to be additionally formed in each layer, the process is very complex. Using various elements such as mold material, adhesive, conductive member material and polyimide may result in the delamination problem due to the difference in a coefficient of thermal expansion (CTE) between elements and the difference of the elements. In addition, the conventional package is unable to be applied to the printed circuit board that has already been mounted with elements.

### SUMMARY

The present invention provides an electronic package and a manufacturing method thereof that forms a chip on chip (COC) package by mounting a high density semiconductor chip on a printed circuit board in which an element is mounted and applies the build-up technology to the printed circuit board.

An aspect of the present invention features an electronic package manufacturing method, including providing a printed circuit board (PCB) having one surface in which a first chip is mounted; attaching one surface of a second chip on the other surface of the PCB, a pad being formed in the other surface of the second chip; encapsulating the second chip by coating the other surface of the PCB with an insulation material; and processing a first via by punching a hole in the insulation material, the first via being electrically interconnected to the pad.

The method can further include a build-up step of processing a second via by stacking a build-up layer in the insulation material and punching a hole in the build-up layer, the second via being electrically interconnected to the first via, after the processing step. A plurality of build-up layers can be stacked in, and the second via can be processed in each of the plurality of build-up layers.

The method can further include a step of forming a conductive bump in a surface of the build-up layer, the conductive bump being electrically interconnected to the second via, after the build-up step. The insulation material and the build-up layer can consist of the same components.

The providing step can include mounting the first chip in one surface of the PCB and electrically interconnecting the first chip to the one surface of the PCB; and molding the first chip by coating the one surface of the PCB with a molding material. The attaching step can include placing an adhesive between the second chip and the PCB and adhering the second chip to the PCB. The encapsulating step can include applying a liquid resin to the PCB to cover the second chip and curing the liquid resin.

The processing step can include punching a via hole by drilling a hole in the insulation material to expose the pad; and forming the first via by plating a surface of the via hole.

Another aspect of the present invention features an electronic package, including a printed circuit board (PCB); a first chip, mounted in one surface of the PCB; a molding material, stacked in the one surface of the PCB and encapsulating the first chip; a second chip, having one surface, which is adhered to the other surface of the PCB, and the other surface, which is formed with a pad; an insulation material, stacked in the other surface of the PCB and encapsulating a second chip; and a first via, having a first land part, which is formed in a surface of the insulation material, and a first penetration part, which is inserted into the insulation material and electrically interconnecting the first land part to the pad.

In the meantime, The electronic package can further include a build-up layer, stacked in the insulation material; and a second via, penetrating the build-up layer and being electrically interconnected to the first via. A plurality of build-up layers can be stacked in, and a plurality of second vias can be processed in each of the plurality of build-up layers, to be electrically interconnected to the build-up layers.

The plurality of second vias can include a plurality of second penetration parts, placed away from each other and penetrating the plurality of build-up layers, respectively; and a plurality of second land parts, formed in each surface of the plurality of build-up layers and electrically interconnected to the second penetration parts.

The electronic package can further include a conductive bump, formed in a surface of the build-up layer and electrically interconnected to the second via. The insulation material and the build-up layer can consist of the same components.

The first chip and the second chip can be electrically interconnected to each other through the first via. The first penetration part can be firmed by forming a via hole by drilling a hole in the insulation to expose the pad and plating a surface of the via hole.

Additional aspects and advantages of the present invention will become apparent and more readily appreciated from the following description, including the appended drawings and claims, or may be learned by practice of the invention.

### BRIEF DESCRIPTION OF THE DRAWINGS

FIG. 1 is a conceptual view showing an electronic package to which the build-up technology is applied in accordance with a conventional art;

FIG. 2 is a flow chart illustrating an electronic package manufacturing method in an embodiment of the present invention;

FIG. 3A through 3N illustrate an electronic package manufacturing method in an embodiment of the present invention; and

FIG. 4 is a sectional view showing an electronic package in an embodiment of the present invention.

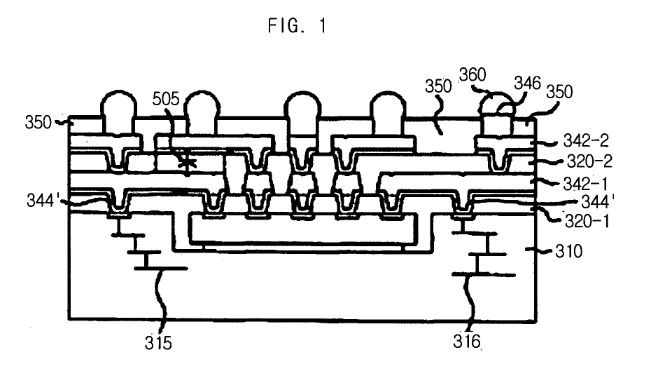

### DETAILED DESCRIPTION

Hereinafter, some embodiments of an electronic package and a manufacturing method thereof in accordance with the present invention will be described in detail with reference to the accompanying drawings. Throughout the drawings, similar or corresponding elements are given similar reference numerals. The pertinent overlapped description will be omitted.

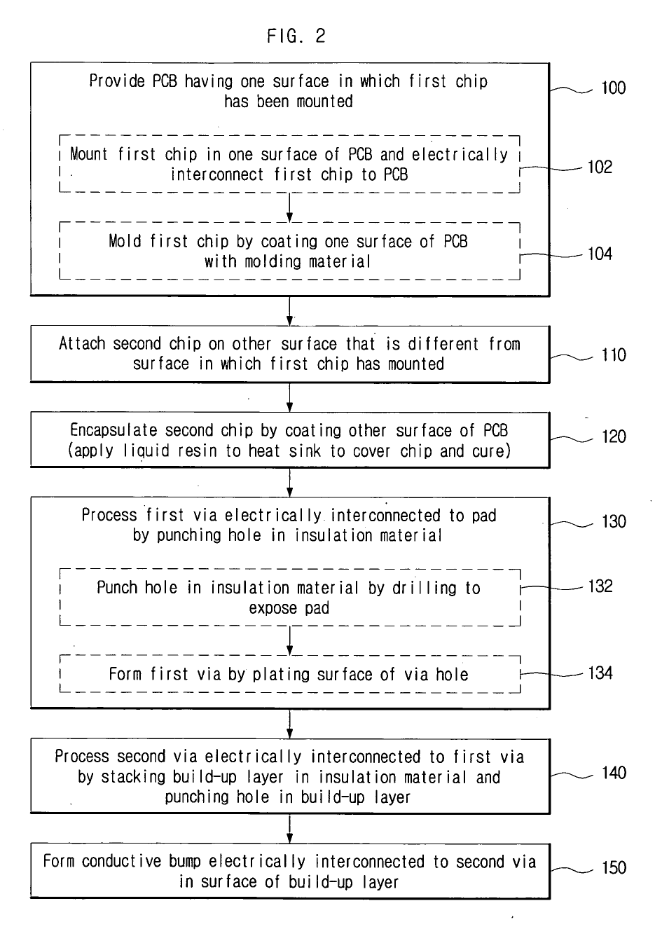

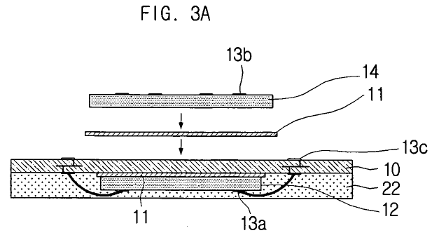

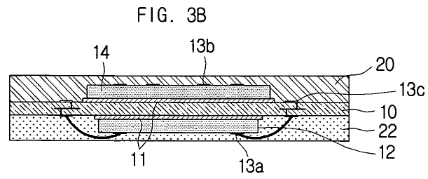

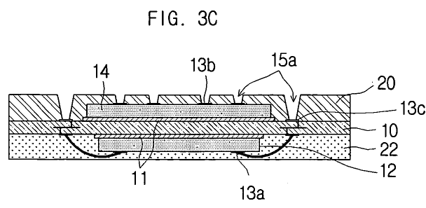

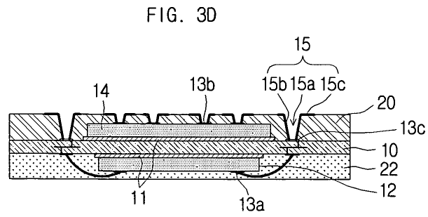

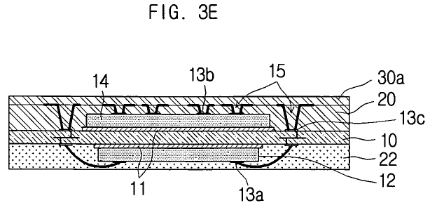

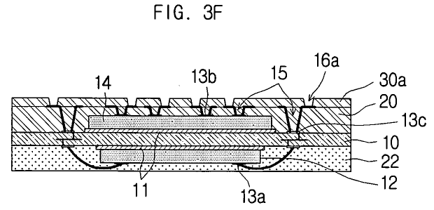

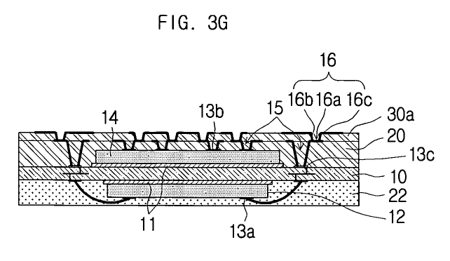

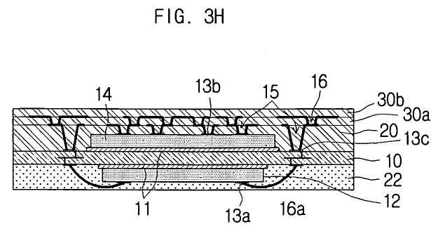

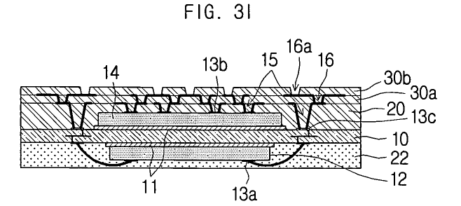

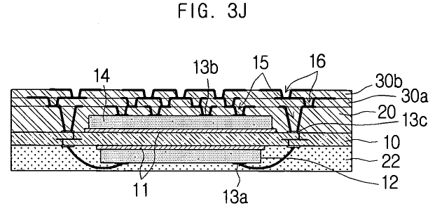

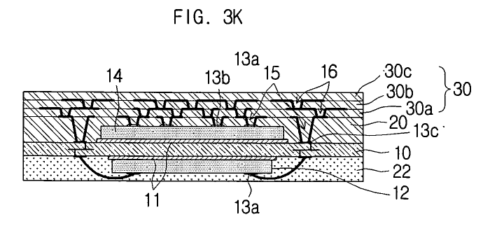

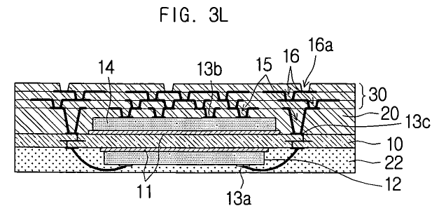

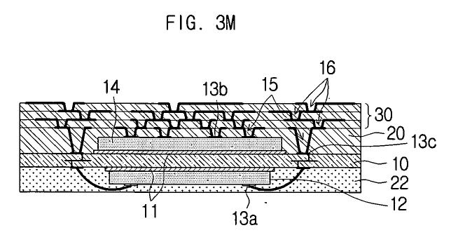

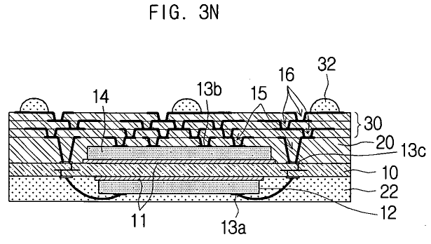

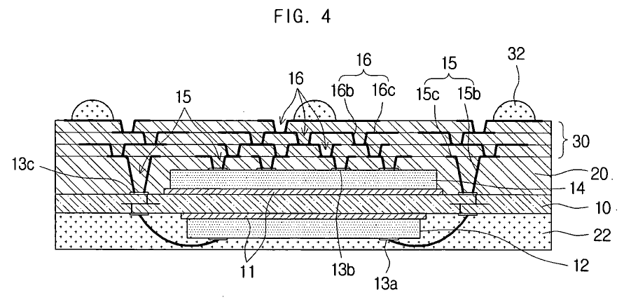

FIG. 2 is a flow chart illustrating an electronic package manufacturing method in an embodiment of the present invention, and FIG. 3A through 3N illustrate an electronic package manufacturing method in an embodiment of the present invention. Referring to FIG. 3A through 4M, a printed circuit board (PCB) 10, an adhesive 11, a first chip 12, pads 13a and 13b, a second chip 14, a first via 15, a first via hole 15a, a first penetration part 15b, a first land part 15c, a second via 16, a second via hole 16a, a second penetration part 16b, a second land part 16c, an insulation material 20, a molding material 22, build-up layers 30a, 30b and 30c (collectively referred to as 30) and a bump 32 are illustrated.

This embodiment is related to the electronic package that can acquire the high reliability with a simpler process without using solder bump by adhering the second chip 14 having high density input/output to one surface of the PCB 10, the other surface of which the first chip 12 has already been mounted in and then applying the build-up technology to realize the electrical interconnection between chips and between the first chip 12 and the second chip 14.

In other words, the embodiment can adhere the second chip 14 having high density input/output to one surface of the PCB 10 in which the first chip 12 is mounted and package the second chip 14, to thereby handle the mounting process of the second chip 14 more stably. As described below, using the same materials for the encapsulation of the second chip 14 and the build-up layer 30 can make it unnecessary to add a separate process for the chip encapsulation. This can result in making the process simple.

In accordance with the embodiment of the present invention, the method of manufacturing the electronic package is described as follows. A step represented by 100 provides the PCB 10 having one surface in which the first chip 12 has been mounted. A step represented by 110 attaches the second chip 14 on the other surface, that is, the surface that is different from the surface in which the first chip 12 has mounted. The adhering process, as shown in FIG. 3A, can be performed by placing the adhesive 11 between the second chip 14 and the PCB 10 and adhering the second chip 24 to the PCB 10. Through this, the second chip 14 can be attached on the PCB 10.

The PCB 10 having the mounted first chip 12 can be provided by the following steps. A step represented by 102 mounts the first chip 12 in one surface of the PCB 10 and electrically interconnects the first chip 12 to the PCB 10. Then, a step represented by 104 molds the first chip 12 by coating the one surface of the PCB with the molding material 22 such as an epoxy molding compound (EMC): Even though FIG. 3A through 3N illustrate the state in which the pad 13a of the first chip 12 is electrically interconnected to the PCB 10 by a wire bonding, the electrical interconnection method and the molding method of the first chip 12 is not limited to this embodiment.

The pad 13b can be formed in one surface of the second chip 14. As described below, the other surface, not formed with the pad 13b, can be adhered to the PCB 10 to expose the one surface formed with the pad 13b as shown in FIG. 3B in order to realize the electrical interconnection for the pad 13b by applying the build-up technology.

As such, the electronic package to be mounted with a plurality of chips can be manufactured by mounting the second chip 14 in one surface of the PCB 10, the other surface of which the first chip 12 is mounted. The first chip 12 and the second chip 14 can be electrically interconnected to each other through the PCB 10. In particular, in the below-described build-up process, the electrical interconnection can be realized directly from the pad through the vias 15 and 16 like the second chip 14 or through the printed circuit board 10 like the first chip 12.

In the state where the chip 14 is attached, as shown in FIG. 3B, a step represented by 120 performs an encapsulating process, which covers the chip, stacked in by coating the PCB 10 with the insulation material 20, by accommodating the chip into the insulation material 20.

Even though the embodiment is based on the state where one semiconductor chip is mounted in the one surface of the PCB as an example, the packaging can be performed by stacking at least two chips or by mounting at least two chips in a horizontal array type and then encapsulating the chips, according to the design of the package.

As shown in FIG. 3B, the encapsulating process can be performed by applying a liquid polyimide (PI) resin to cover the stacked chip and curing the chip. As described below, a dielectric layer having a predetermined thickness is required to be formed in the encapsulated second chip 14 to perform the build-up process forming an electric connection path by punching a via hole in the insulation material. However, in the case of applying and then hardening the liquid PI resin like this embodiment, the chip encapsulation and the first insulation layer formation can be performed together, to thereby simplify the process.

After the insulation material 20 is hardened, a step represented by 130 processes the first via 15 corresponding to the position of the pad 13b of the second chip 14 by applying the build-up technology. Particularly, a step represented by 132 punches a hole in the insulation material 20 by using a laser drill to expose the pad 13b as shown in FIG. 3C. A step represented by 134 forms a conductive layer by applying a process such as a cupper sputtering process and a conductive paste charging process to the surface of a first via hole 15a. Since the electrical interconnection with the first chip 12 can be realized through the via 15, it can be preferably that the first via hole 15a is punched to expose not only the pad 13b of the second chip 14 but also the pad 13c of the PCB 10 to which the first chip is electrically interconnected.

Accordingly, the pad 13b of the embedded second chip 14 can be electrically interconnected to an outside. Of course, the drilling process used for punching the via hole and the plating process for electrical interconnection for the via hole is not limited to the aforementioned embodiment.

As shown in FIG. 3D, in case that the first via 15 is formed by punching the first via hole 15a in the insulation material 20 and plating the surface of the first via hole 15a, the first via 15 can consist of a first part, penetrating the insulation material 20 and forming an electrical path with the pad 13b of the second chip 14, and a second part, connected to the first part and partially stacked in the surface of the insulation material 20. Hereinafter, the first part is referred to as the penetration part, and the second part is referred to as the land part. In other words, the first via 15 can include a first via hole 15a, a first penetration part 15b and a first land part 15c.

Then, the electrical path with the semiconductor can be formed by continuing the build-up process as necessary. How many build-up layers 30 are stacked in and how the via hole is processed can be changed depending on the design of the electronic package. FIG. 3A through FIG. 3N illustrate the case of stacking a total of 3 build-up layers 30a, 30b, 30c (collectively referred to as 30) and being coupled to the solder ball bump.

In other words, as shown in FIG. 3E, a first build-up layer 30a can be stacked in the insulation material 20. The build-up layer 30a can consist of an insulation component. The build-up layer 30a can be realized by applying and hardening a liquid PI or stacking PI films. Here, the liquid PI can have the same component as the insulation material 20.

In case that the build-up layer 30 has the same component as the insulation material 20, the build-up process, which is the encapsulating process of the chip and the stacking process of the build-up layer 30, can be performed as the same process, to thereby have high processability and low cost. Also, since the contraction and expansion of the electronic package by heat, generated by the chip, are not differently changed in the insulation material 20 and the build-up layer 30, an error by the thermal stress can be prevented. Accordingly, when it is said that the insulation material 20 has the same component as the build-up layer 30 in accordance with the present invention, the same component indicates the ‘same kind of component’ having the same properties in processability, cost and contraction and expansion by heat as well as the same material.

Then, a step represented by 140 punches a second via hole 16a by drilling a hole in the first build-up layer 30a at the position of the first via 15 as shown in FIG. 3F and forms a first via 16 by plating the internal surface of a second via hole 16a. Similarly to the first via 15, the second via 16 can consist of the second via hole 16a, a second penetration part 16b and a second land part 16c. As shown in FIG. 3G, the second penetration 16b can be electrically interconnected to the first land part 15c by punching the second via hole 16a to expose the first land part 15c. Accordingly, the electrical path can be realized from the pads 13b and 13c with the PCB 10 and the semiconductor chip 14.

FIG. 3A through 3N illustrates the example of the build-up process stacking the 3 build-up layers. Here, the build-up process is firstly repeated 3 times. In other words, a second build-up layer 30b is stacked in as shown in FIG. 3H, and the second via hole 16a is punched at the position of the second via 16 of the first build-up layer 30a as shown in FIG. 3I. And then, the second via 16 is further interconnected to the second build-up layer 30b by plating the punched second via hole 16a as shown in FIG. 3J.

In the case of the third build-up layer 30c, the build-up process is repeated. The third build-up layer 30c is stacked in as shown in FIG. 3K, and the second via hole 16a is punched at the position of the second via 16 of the second build-up layer 30b. Then, the second via 16 is further interconnected to the second build-up layer 30c by plating the punched second via hole 16a as shown in FIG. 3M

As described above, the build-up process can be performed repeatedly as necessary according to the design of the electronic package. Accordingly, a plurality of build-up layers 30 can be stacked in and the second via 16 can be formed in each build-up layer, to thereby realize each corresponding electrical path. Similarly to the electrical interconnection with the first via 15, the electrical interconnection with the second via 16 can be realized by connecting the second land part 16c of a n^{th} build-up layer to the second penetration part 16b of a (n+1)^{th} build-up layer.

After the build-up process is completed, as shown in FIG. 3N, a step represented 150 forms a pad for electrically interconnecting the electronic package to an external apparatus by coupling a conductive bump such as a solder ball to the second land 16c formed in the surface of the build-up layer 30.

FIG. 4 is a sectional view showing an electronic package in an embodiment of the present invention. Referring to FIG. 4, a PCB 10, an adhesive 11, a first chip 12, pads 13a and 13b, a second chip 14, a first via 15, a first penetration part 15b, a first land part 15c, a second via 16, a second penetration part 16b, a second land part 16c, an insulation material 20, a molding material 22, a build-up layer 30 and a bump 32 are illustrated.

In accordance with the embodiment of the present invention, the electronic package can be configured to realize the electrical interconnection by adhering an input/output chip to the PCB 10 having a mounted device with the adhesive 11. An electrical path from the mounted chip can be formed from a pad of an upper part of the chip by applying the build-up technology. A bump can be coupled to the most upper part of the build-up layer 30 for the surface mount technology (SMT).

In other words, since the electrical path from the PCB or the semiconductor chip is realized by performing the build-up process from pads 13b and 13c, it is possible to realize a find pitch. For example, if it is assumed that the conventional bump ball technology realizes an about 100 micrometer pitch, the build-up technology in accordance with the embodiment of the present invention can realize an about 30 micrometer pitch, to thereby miniature the package.

As illustrated in FIG. 4, in accordance with the embodiment of the present invention, since the electronic package is manufactured by adhering the second chip 14 to one surface of the PCB 10 and encapsulating the PCB 10 with the insulation material, it is possible to perform the handling more stably in the packaging process of the second chip 14, the first chip 12 having already been mounted in the other surface of the PCB 10.

As described above, since the first chip 12 has already been mounted and molded by using the molding material 22 in one surface, when the second chip 14 is attached on the other surface of the PCB 10 and the build-up process is performed, the package handling can be more stably performed.

The process of attaching the second chip 14 on the other surface of PCB 10 can be less expensively and more promptly performed by using the adhesive 11. The second chip 14 to be adhered to PCB 10 makes it possible to realize the electrical path by the build-up process by allowing the pad 13b to be exposed.

The second chip 14 adhered to the other surface of the PCB 10 can be encapsulated by using the insulation material 20, for example, by applying a liquid PI resin. The molding of the semiconductor can be performed by encapsulating the semiconductor with the existing molding material such as an epoxy molding compound (EMC). Alternatively, using the same material such as the PI resin as the build-up layer 30 makes it possible to perform the chip encapsulating process and the build-up process as the same process, to thereby simplify the process and prevent the package error by the difference in properties between materials.

The insulation material 20 accommodating the second chip 14 inside and being encapsulated can form the electrical path with the PCB 10 and the second chip 14 by allowing the first via 15 to be inserted to the insulation material 20. The first via 15 can include a first land part 15c, formed in the surface of the insulation material 20, and a first penetration part 15b, inserted into the insulation material 20. As described with reference to FIG. 3A through 3N, the first penetration part 15b can be formed by drilling the via hole in the insulation material 20 and plating the surface of the via hole. Accordingly, the first via 15 can realize the electrical path with the chips in a shape being insulted into the insulation material 20. Also, the first chip 12, mounted in one surface of PCB 10, and the second chip 14, adhered to the other surface of PCB 10 can be electrically interconnected to each other through the first via 15.

If the build-up process in accordance with the present invention is applied, at least one build-up layer 30 can be stacked in the insulation material 20, and the second via 16, electrically interconnected to the first via 15, can be inserted into the build-up layer 30. The second via 16 can be formed in each build-up layer 30 in order to form pads 13b and 13c with the PCB 10 and the second chip 14.

Similarly to the first via 15, the second via 16 can include a second penetration part 16b, inserted into the build-up layer 30, and a second land part 16c, stacked in the surface of the build-up layer 30. A plurality of second vias 16 formed in each build-up layer 30, as shown in FIG. 4, can be formed to have the structure in which the second penetration part 16b of any one build-up layer 30 and the second land part 16c of a layer close to the build-up layer 30 can be electrically interconnected to each other. This structure can be formed by applying the build-up process in order to realize the electrical path from the pads 13b and 13c. It is unnecessary that the penetration part is in contact with the land part. Alternatively, the electrical path can be realized in the stack via structure, in which the penetration parts are interconnected to each other, or the through hole structure, in which all stacked build-up layers is penetrated.

After the build-up process is completed, a conductive bump such as a solder ball can be coupled to the surface of the build-up layer 30 to allow the electronic package to be interconnected to an external apparatus through the surface mount technology. The conductive bump can be electrically interconnected to the second via 16 formed in the build-up layer 30, to thereby form the pad for electrically interconnecting the electronic package to an external apparatus.

A lot of other embodiments can described within the principles and spirit of the invention, the scope of which shall be defined by the appended claims.

What is claimed is:

1. An electronic package manufacturing method comprising:
providing a printed circuit board (PCB) having one surface in which a first chip is mounted;
attaching one surface of a second chip on the other surface of the PCB, a pad being formed in the other surface of the second chip;
encapsulating the second chip by coating the other surface of the PCB with an insulation material; and
processing a first via by punching a hole in the insulation material, the first via being electrically interconnected to the pad.

2. The method of claim 1, further comprising a build-up step of processing a second via by stacking a build-up layer in the insulation material and punching a hole in the build-up layer, the second via being electrically interconnected to the first via,
after the processing step.

3. The method of claim 2, wherein a plurality of build-up layers are stacked in, and the second via is processed in each of the plurality of build-up layers.

4. The method of claim 2, further comprising a step of forming a conductive bump in a surface of the build-up layer, the conductive bump being electrically interconnected to the second via,
after the build-up step.

5. The method of claim 2, wherein the insulation material and the build-up layer consist of the same components.

6. The method of claim 1, wherein the providing step comprises
mounting the first chip in one surface of the PCB and electrically interconnecting the first chip to the one surface of the PCB; and
molding the first chip by coating the one surface of the PCB with a molding material.

7. The method of claim 1, wherein the attaching step comprises placing an adhesive between the second chip and the PCB and adhering the second chip to the PCB.

8. The method of claim 1, wherein the encapsulating step comprises applying a liquid resin to the PCB to cover the second chip and curing the liquid resin.

9. The method of claim 1, wherein the processing step comprises
punching a via hole by drilling a hole in the insulation material to expose the pad; and
forming the first via by plating a surface of the via hole.

10. An electronic package comprising:
a printed circuit board (PCB);
a first chip, mounted in one surface of the PCB;
a molding material, stacked in the one surface of the PCB and encapsulating the first chip;
a second chip, having one surface, which is adhered to the other surface of the PCB, and the other surface, which is formed with a pad;
an insulation material, stacked in the other surface of the PCB and encapsulating a second chip; and
a first via, having a first land part, which is formed in a surface of the insulation material, and a first penetration part, which is inserted into the insulation material and electrically interconnecting the first land part to the pad.

11. The electronic package of claim 10, further comprising
a build-up layer, stacked in the insulation material; and
a second via, penetrating the build-up layer and being electrically interconnected to the first via.

12. The electronic package of claim 11, wherein a plurality of build-up layers are stacked in, and a plurality of second vias are processed in each of the plurality of build-up layers, to be electrically interconnected to the build-up layers.

13. The electronic package of claim 12, wherein the plurality of second vias comprises
a plurality of second penetration parts, placed away from each other and penetrating the plurality of build-up layers, respectively; and
a plurality of second land parts, formed in each surface of the plurality of build-up layers and electrically interconnected to the second penetration parts.

14. The electronic package of claim 11, further comprising a conductive bump, formed in a surface of the build-up layer and electrically interconnected to the second via.

15. The electronic package of claim 11, wherein the insulation material and the build-up layer consist of the same components.

16. The electronic package of claim 10, wherein the first chip and the second chip are electrically interconnected to each other through the first via.

17. The electronic package of claim 10, wherein the first penetration part is firmed by forming a via hole by drilling a hole in the insulation to expose the pad and plating a surface of the via hole.
